(19) United States
(12) Patent Application Publication
(10) Pub. No.: US 2019/0108943 A1
(43) Pub. Date: Apr. 11, 2019

(54) HIGH VOLTAGE CAPACITORS AND METHODS OF MANUFACTURING THE SAME

(71) Applicant: Texas Instruments Incorporated, Dallas, TX (US)

(72) Inventors: Gang Liu, Richardson, TX (US); Qi-Zhong Hong, Richardson, TX (US)

(21) Appl. No.: 15/730,508

(22) Filed: Oct. 11, 2017

(51) Int. Cl. H01G 4/01; H01G 4/04; H01G 4/005; H01G 4/18; H01G 4/224; H01L 29/66

(52) U.S. Cl. CPC H01G 4/01; H01G 4/04; H01G 4/005; H01L 29/92; H01G 4/224; H01L 29/66181; H01G 4/18

(57) ABSTRACT

High voltage capacitors and methods of manufacturing the same are disclosed. An apparatus includes a first electrode of a capacitor above a semiconductor substrate. The first electrode is parallel to a plane perpendicular to the substrate. The apparatus further includes a second electrode spaced apart from the first electrode and parallel to the plane. The first electrode and the second electrode each including: (1) a first metal segment in a first metal layer, (2) a second metal segment in a second metal layer, and (3) a conductive via in an intermetal dielectric layer between the first and second metal layers interconnecting the first and second metal segments.

### FIELD OF THE DISCLOSURE

This disclosure relates generally to semiconductor devices, and, more particularly, to high voltage capacitors and methods of manufacturing the same.

### BACKGROUND

Capacitors are often manufactured using two conductive electrodes spaced a distance apart with a dielectric material disposed therebetween. The capacitance of such devices proportionately relates to the surface areas of the electrodes and inversely relates to the distance between the electrodes. That is, capacitance increase as the electrodes increase in size and the distance between them decreases. However, the minimum distance between electrodes in a capacitor is limited by the breakdown voltage of the dielectric material disposed between the electrodes. Thus, manufacturing high voltage capacitors typically involves using larger electrodes spaced farther apart, thereby resulting in a lower capacitance density than comparable capacitors rated for a lower voltage.

### BRIEF DESCRIPTION OF THE DRAWINGS

FIG. 1 illustrates a top view of an example layout of electrodes for an example capacitor.

FIG. 2 is a cross-sectional view of the example capacitor of FIG. 1, taken along line 2-2 of FIG. 1, constructed using known techniques.

FIG. 3 illustrates a top view of an example layout of electrodes for an example capacitor constructed in accordance with the teachings disclosed herein.

FIG. 4 is a cross-sectional view of the example capacitor of FIG. 3, taken along line 4-4 of FIG. 3.

FIG. 5 is a top perspective cut-away view of the example capacitor of FIGS. 3 and 4 cut along line 5-5 of FIG. 4.

FIG. 6 is a cross-sectional view of the example capacitor of FIGS. 3-5 taken along line 6-6 shown in each of FIGS. 3, 4, and 5.

FIG. 7 is a top perspective cut-away view of another example capacitor constructed in accordance with the teachings disclosed herein.

FIG. 8 is a cross-sectional view of the example capacitor of FIG. 7 taken along line 8-8 of FIG. 7.

FIGS. 9-14 illustrate progressive stages in the manufacturing of the example capacitors of FIGS. 3-8.

FIG. 15 is a flowchart representative of an example method to manufacture the example capacitors of FIGS. 3-8.

FIG. 16 is a block diagram of an example processor system associated with one or more semiconductor fabrication machines to execute example machine readable instructions represented at least in part by the example method of FIG. 15 to manufacture the example capacitors of FIGS. 3-8.

The figures are not to scale. Instead, to clarify multiple layers and regions, the thickness of the layers may be enlarged in the drawings. Wherever possible, the same reference numbers will be used throughout the drawing(s) and accompanying written description to refer to the same or like parts. As used in this patent, stating that any part (e.g., a layer, film, area, or plate) is in any way positioned on (e.g., positioned on, located on, disposed on, or formed on, etc.) another part, indicates that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

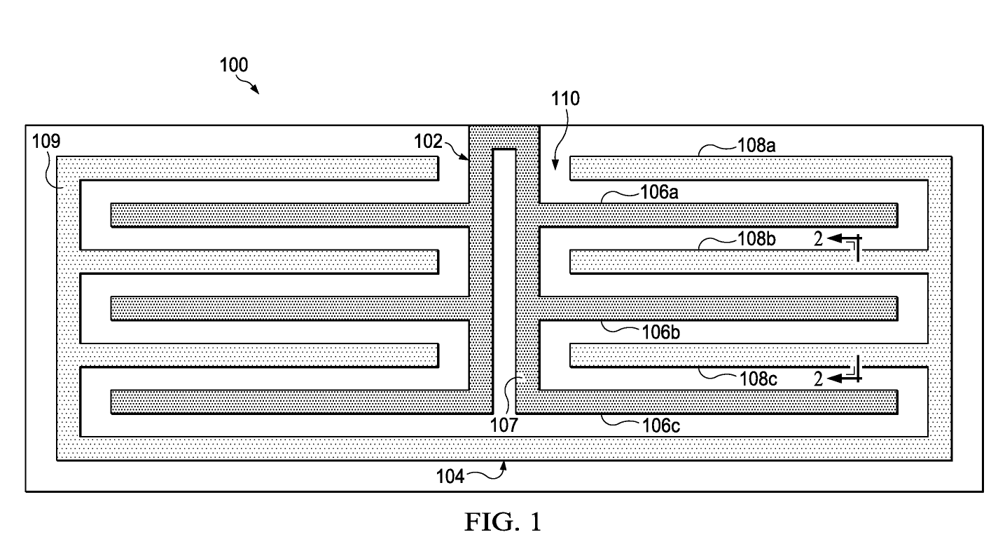

While the two electrodes in a capacitor may be of any suitable arrangement, a common approach is illustrated in FIG. 1. In particular, FIG. 1 illustrates a top view of an example layout of electrodes for an example capacitor 100. As shown in the illustrated example, the capacitor 100 includes a first electrode 102 (represented with dark shading) positioned in close proximity with a second electrode 104 (represented with light shading). In the illustrated example, the first electrode 102 has a comb-like structure that includes a first series of teeth 106a, 106b, 106c (collectively referred to with the reference numeral 106) branching out from a stem 107 that interweave with a second series of teeth 108a, 108b, 108c (collectively referred to with the reference numeral 108) branching out from a stem 109 associated with the comb-like structure of the second electrode 104. The comb-like structures of the first and second electrodes 102, 104, with the interweaved teeth 106, 108, increases the surface area of the electrodes 102, 104 in proximity with one another to increase the capacitance of the capacitor. In the illustrated example, a dielectric material 110 is disposed between electrodes 102, 104. The electrodes 102, 104 are constructed to be spaced apart at a distance defined by the desired voltage for the capacitor in conjunction with the breakdown voltage of the dielectric material 110.

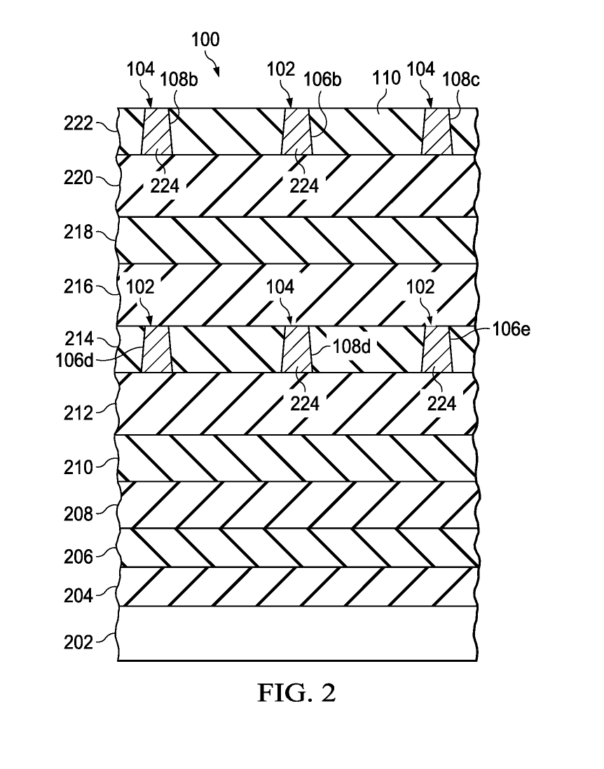

Often, the electrodes 102, 104 are formed during the back-end-of-line (BEOL) processing of semiconductor device fabrication. FIG. 2 is a cross-sectional view of the example capacitor 100 of FIG. 1, where the cross-sectional view corresponds to line 2-2 of FIG. 1, showing different layers 202-222 formed during the fabrication of the capacitor 100 including layers formed during BEOL processes. BEOL processes include the deposition of one or more metal layers isolated by layers of dielectric material. BEOL processing is sometimes referred to as metallization. The metal layers formed during the BEOL serve to interconnect transistors and/or other devices formed on a semiconductor substrate (e.g., a silicon wafer). In contrast to BEOL processes, the preparation of the semiconductor substrate and the formation of the transistors and/or other devices thereon is referred to as front-end-of-line (FEOL) processes.

Turning in detail to FIG. 2, fabrication of the example capacitor 100 begins with a semiconductor substrate 202 that may include one or more transistors or other semiconductor devices. The formation of such transistors may correspond to the end of the FEOL processes that are then followed by BEOL processes. At the beginning of BEOL processing, a first layer 204 of dielectric material is added to the semiconductor substrate 202. The first layer 204 is referred to as the pre-metal dielectric (PMD) layer because it is formed prior to the deposition of metal. Example materials for the PMD layer 204 include silicon dioxide but any other suitable dielectric may alternatively be used.

After formation of the PMD layer 204, a first metal layer 206 is formed followed by a first intermetal dielectric (IMD) layer 208. In the illustrated example, alternating layers of successive metal layers 210, 214, 218, 222 and IMD layers 212, 216, 220 ending with a fourth IMD layer 220 followed by a fifth metal layer 222. Typically, the metal layers 206, 210, 214, 218, 222 are formed by depositing a layer of metal on the underlying dielectric material and then etching away undesired portions to leave particular metal segments 224 in an arrangement corresponding to a pattern associated with the particular metal layer being formed. The space between the remaining metal segments 224 is then filled with additional dielectric material (e.g., the dielectric material 110) to complete the metal layer. In the illustrated example, different ones of the metal segments 224 in the metal layers 206, 210, 214, 218, 222 correspond to different ones of the teeth 106, 108 of the electrodes 102, 104 with the remaining portions of the respective metal layers corresponding to dielectric material. In some examples, the metal used in the metal layers 206, 210, 214, 218, 222 is copper but any other suitable conductor may be used. The IMD layers 208, 212, 216, 220 and/or the dielectric material within the metal layers 206, 210, 214, 218, 222 are often formed of the same dielectric material as used in the PMD layer 204 but any other suitable dielectric insulator may alternatively be used.

In many semiconductor fabrication processes, the metal in separate metal layers 206, 210, 214, 218, 222 are interconnected with one or more conductive vias formed in the IMD layers 208, 212, 216, 220. Typically, vias are formed by etching holes in a particular IMD layer and then filling the holes with a conductive material (e.g., tungsten) to form a column or pillar-like structure that extends between the metal layer below the IMD layer and a subsequent metal layer formed thereafter to provide electrical connectivity between the metal layers. In the illustrated example of FIG. 2, no conductive vias are included because the metal segments 224 in the separate metal layers 206, 210, 214, 218, 222 correspond to separate fingers or teeth 106, 108 of the electrodes 102, 104 of the example capacitor 100. Thus, as shown in the illustrated example of FIG. 2, the individual teeth 106b, 108b, 108c are formed in the fifth metal layer 222 with different teeth 106d, 106e, 108d formed in the third metal layer 214. As a result, the individual teeth 106, 108 of the illustrated example are laterally separated (within each corresponding metal layer 214, 222) and vertically separated (between different metal layers 214, 222) by the dielectric material 110. Although the teeth 106 are spaced apart in the illustrated example, all of the first series of teeth 106 (including the individual teeth 106b, 106d, and 106e shown in FIG. 2) are electrically coupled to form the first electrode 102. In some examples, the separate teeth 106b, 106d, and 106e in separate metal layers 214, 222 are electrically coupled by vias along the stem 107 of the first electrode 102. Similarly, all of the second series of teeth 108 (including the individual teeth 108b, 108c, 108d shown in FIG. 2) are electrically coupled to form the second electrode 104.

Furthermore, as shown in FIG. 2, the separate teeth 106, 108 associated with the respective first and second electrodes 102, 104 alternate positions between adjacent metal layers where the teeth 106, 108 are located. That is, the teeth 106d, 106e associated with the first electrode 102 in the third metal layer 214 shown in FIG. 2 are on the left and right sides of the drawing whereas the teeth 108b, 108c associated with the second electrode 104 in the fifth metal layer 214 are on the corresponding left and right sides of the drawing. Alternating the arrangement of the teeth 106, 108 of the electrodes 102, 104 in this manner enables capacitive coupling between the electrodes in both a lateral direction (e.g., in a plane parallel to the underlying semiconductor substrate 202 or any other one of the layers 204-222) and a vertical direction (e.g., in direction perpendicular to the underlying semiconductor substrate 202 and other layers 204-222).

Forming high voltage capacitors during typical BEOL processes within alternating teeth 106, 108 in both vertical and lateral directions, as described above, presents certain challenges because of the thickness of the layers 204-222, which are substantially fixed for standard BEOL processes. In particular, the IMD layers 208, 212, 216, 220 in typical BEOL processes are too thin to establish capacitance between separate teeth 106, 108 of the electrodes 102, 104 formed in directly adjacent metal layers 206, 210, 214, 218, 222 when the voltage across the electrodes 102, 104 is high. As used herein, high voltage refers to a voltage greater than 80 V (e.g., 100 V, 150 V, 200 V, etc.).

To overcome this difficulty and enable capacitive coupling between adjacent teeth 106, 108 of the electrodes 102, 104 in the vertical direction, some of the metal layers do not include any metal. More particularly, in the illustrated example, the first, second, and fourth metal layers 206, 210, 218 do not include any metal, thereby leaving only the third and fifth metal layers 214, 222 with metal segments 224 defining the teeth 106, 108 of the electrodes 102, 104 of the capacitor 100. Thus, rather than capacitance being established between two electrodes across a single IMD layer, the vertical coupling of the electrodes 102, 104 spans the gap defined by the combined thickness of the third IMD layer 216, the fourth metal layer 218, and the fourth IMD layer 220. The arrangement of the metal segments 224 (e.g., the individual teeth 106, 108) in the illustrated example of FIG. 2 is suitable for a 200 V capacitor. Thus, the formation of a high voltage capacitor is possible in existing BEOL layers using known techniques. However, the extra spacing between the electrode teeth 106, 108 by skipping metal layers, as shown in the illustrated example of FIG. 2, results in a capacitance density estimated to be around 0.01 femtofarads per square micrometer (fF/um²). This is considerably less than may be desired in many applications.

Examples disclosed herein enable the formation of high voltage capacitors with significantly increased capacitance density than is possible using the approach described in connection with FIG. 2. More particularly, examples disclosed herein enable the manufacture of 200 V capacitors with a capacitance density more than twice (e.g., at least 0.02 fF/um²) that estimated for the example capacitor of FIG. 2. The examples disclosed herein are not limited to high voltage applications but may be implemented for lower voltage applications as well. In such examples, even higher capacitance densities may be possible.

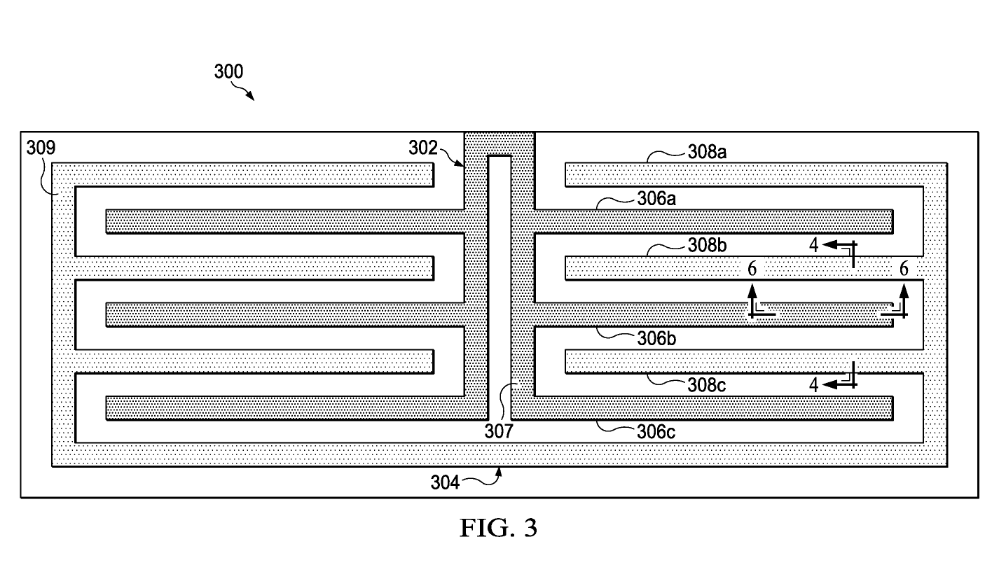

Example capacitors constructed in accordance with the teachings disclosed herein achieve higher capacitance densities by constructing each electrode as a wall or plate formed from multiple metal layers formed during BEOL processes that are interconnected by conductive vias as shown in the illustrated examples of FIGS. 3-7. In particular, FIG. 3 illustrates a top view of an example layout of electrodes for an example capacitor 300 constructed in accordance with the teachings disclosed herein. The layout of the example capacitor 300 of FIG. 3 is arranged similarly to the example capacitor 100 shown in FIG. 1. That is, the example capacitor 300 includes a first electrode 302 with a first series of teeth 306a, 306b, 306c (collectively referred to with the reference numeral 306) branching from a stem 307 and that interweave with a second series of teeth 308a, 308b, 308c (collectively referred to with the reference numeral 308) branching out from a stem 109 associated with a second electrode 304. While the top view layout of the electrodes 302, 304 of FIG. 3 is similar to the top view layout of the electrodes 102, 104 of FIG. 1, the structure of the electrodes 302, 304 is significantly different when viewed in cross-section.

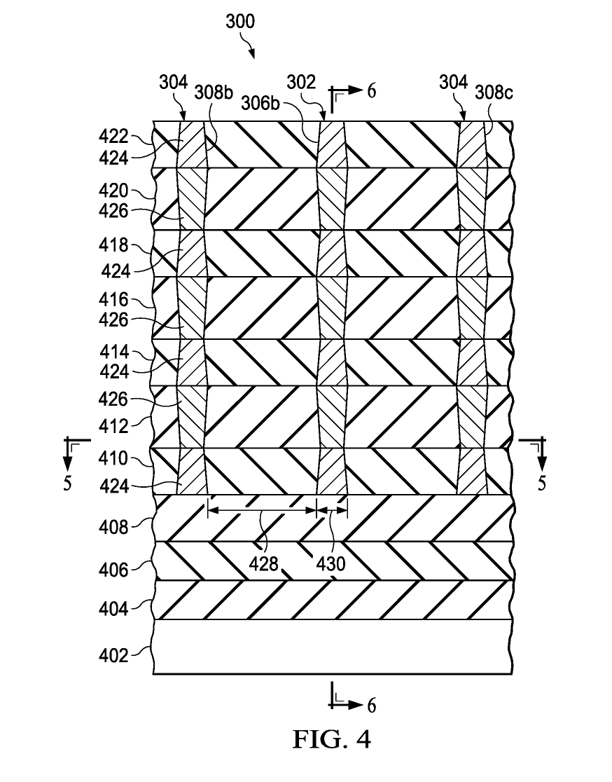

FIG. 4 is a cross-sectional view of the example capacitor 300 of FIG. 3, where the cross-sectional view corresponds to line 4-4 of FIG. 3. Thus, the cross-sectional view shown in FIG. 4 of the capacitor 300 of FIG. 3 is comparable to the cross-sectional view shown in FIG. 2 of the capacitor 100 of FIG. 1. In the illustrated example of FIG. 4, the capacitor 300 includes a semiconductor substrate 402 and subsequent layers 404-422 that are similar to the semiconductor substrate 202 and subsequent layers 204-222 described above in connection with FIG. 2. However, as shown in the illustrated example, the arrangement of metal in many of the layers is different for the capacitor 300 of FIG. 4 than for the capacitor 100 of FIG. 2. In particular, unlike the electrodes 102, 104 of FIG. 2 that includes separate teeth 106, 108 at different metal layers, the teeth 306, 308 in FIG. 4 are arranged as a stacked series of metal segments 424 in respective metal layers 410, 414, 418, 422 electrically interconnected by conductive vias 426 extending between the vertically adjacent metal segments 424. Thus, while each metal segment 424 may correspond to an elongate finger or strip of metal, in some examples, a combined shape of the metal segments 424 and associated vias 426 (corresponding to individual teeth 306b, 308b, 308c of each electrode 302, 304) generally corresponds to a wall or plate of metal along a plane substantially perpendicular (e.g., perpendicular or within 5 degrees of being perpendicular) to the semiconductor substrate 402 and the individual layers 404-422. In some examples, as described more fully below, the vias 426 are also elongate and extend continuously along the length of the metal segments 424 such that the combined shape of each of the individual teeth 306b, 308b, 308c is a wall or plate of solid metal without holes or gaps containing dielectric material within a plane along the defined wall.

Unlike the capacitor 100 of FIG. 2, there is no capacitive coupling in the vertical direction in the example capacitor 300 of FIG. 4 because all the metal segments 424 in the same vertical plane are electrically interconnected by the vias 426 so as to be at the same voltage potential. Put another way, all metal in the same vertical plane corresponds to the same electrode 302, 304 of the example capacitor 300 of FIG. 4. As a result of this arrangement, the thickness of the layers 404-422 in the example capacitor 300 of FIG. 4 is irrelevant to the resulting capacitance of the capacitor 300. Rather, the only distance between the teeth 306, 308 that defines capacitance is the width 428 of the gap between the individual teeth (or walls) 306, 308 (e.g., between the tooth 306b and the tooth 308b) in the lateral direction where lateral capacitive coupling still occurs. That is, in the illustrated example of FIG. 4, capacitive coupling between the first and second electrodes 302, 304 is limited to lateral coupling without capacitive coupling in a vertical direction.

The width of the gap between adjacent teeth 306, 308 may be determined based on the electrical field the dielectric between the teeth 306, 308 of the electrodes 302, 304 can safely sustain for a reasonably good lifetime (e.g., 10 years). As a specific example, for a 200 V capacitor, the width of the gap between adjacent teeth 306, 308 may be as small as 1 micrometer. The width 428 of the gap is exaggerated relative to a thickness 430 of the metal segments 424 in the illustrated example of FIG. 4 for purposes of clarity. In some examples, the thickness 430 of the metal segments 424 is approximately 0.5 micrometers. Of course, the thickness 430 of the metal segments 424 may be of any suitable thickness. Similarly, the width 428 of the gap can be controlled to any desirable distance based on the pattern used to etch each metal layer 406, 410, 414, 418, 422. This provides much greater control of the resulting capacitance than is possible when limited to certain fixed distances corresponding to combinations of the thicknesses of the separate layers 404-422 formed during the BEOL processes as shown and described in connection with FIG. 2 with respect to the corresponding layers 204-222. Further, although the vias 426 in FIG. 4 are shown as having approximately the same thickness as the metal segments 424, in other examples, the vias 426 may be wider or thinner than the associated metal segments 424.

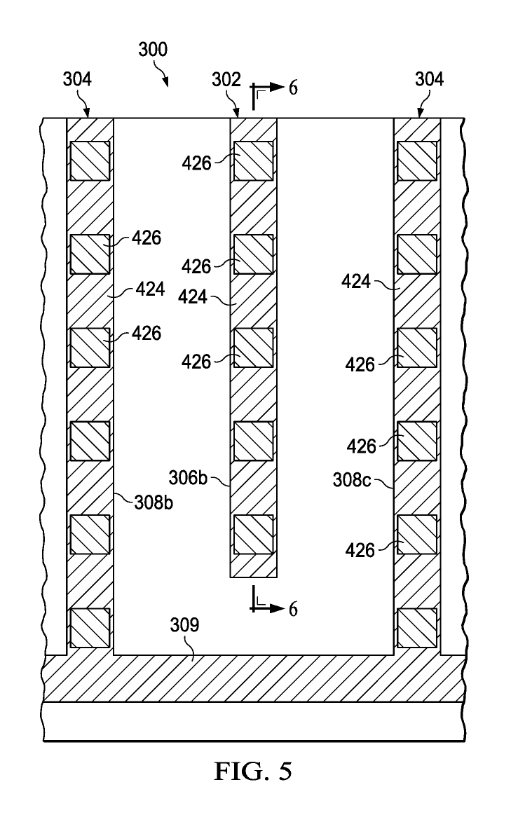

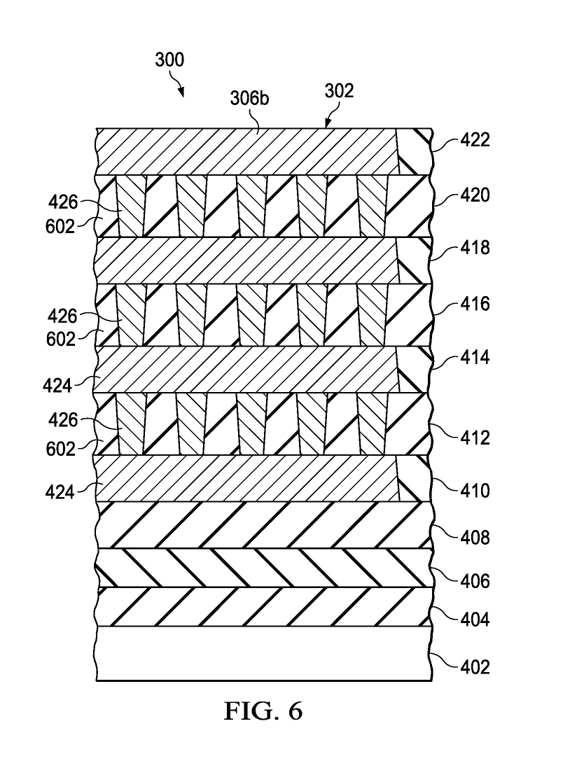

FIG. 5 is a top perspective cut-away view of the example capacitor 300 of FIGS. 3 and 4 cut along line 5-5 of FIG. 4 with the dielectric material omitted for purposes of explanation. FIG. 6 is a cross-sectional view of the example capacitor 300 of FIGS. 3-5 taken along line 6-6 shown in each of FIGS. 3, 4, and 5. In other words, FIG. 6 is a cross-sectional view taken along a length of the center tooth 306b of the first electrode 302 of FIGS. 3-5. In some example, as shown in FIGS. 5 and 6, multiple vias 426 are formed along the length of each of the individual teeth 306b, 308b, 308c. Additionally or alternatively, the vias 426 may be formed on the stem of the electrodes 302, 304 (e.g., the stem 309 of the second electrode 304 shown in FIG. 5).

The vias 426 of the illustrated example of FIGS. 5 and 6 are formed using traditional methods to form conductive vias in which a hole is etched in the dielectric material of the IMD layer and then filled with metal. In this manner, each via 426 in the illustrated example has a generally column-like or pillar-like structure. The vias 426 may be spaced apart at any suitable distance. In some examples, only a single via 426 may be provided to electrically interconnect the metal segments 424 formed in separate metal layers 406, 410, 414, 418, 422. However, increasing the number of vias 426 increases the overall area of the teeth 306, 308 of each electrode 302, 304, which contributes to the capacitance of the example capacitor 300. When many vias 426 are included, as shown in the illustrated example, the metal segments 424 and the vias 426 associated with each of the teeth 306, 308 forms a metal grating or wall with gaps 602 filled with dielectric material.

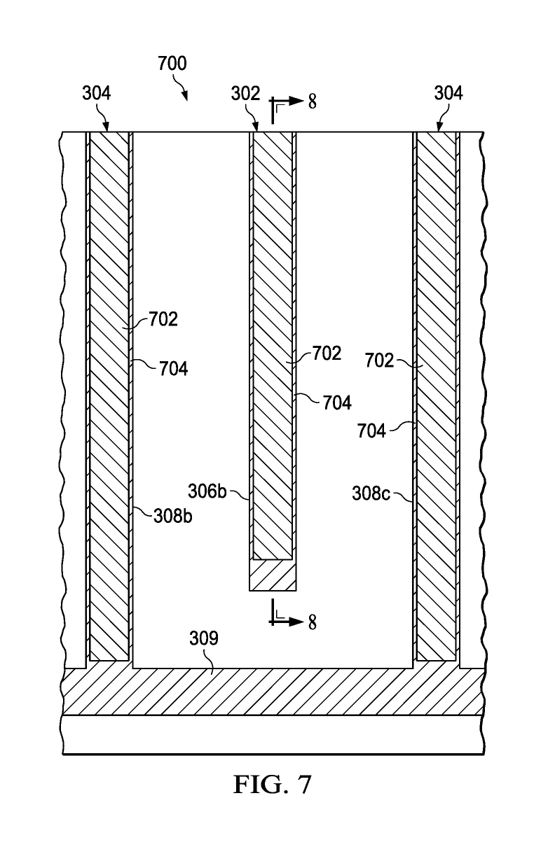

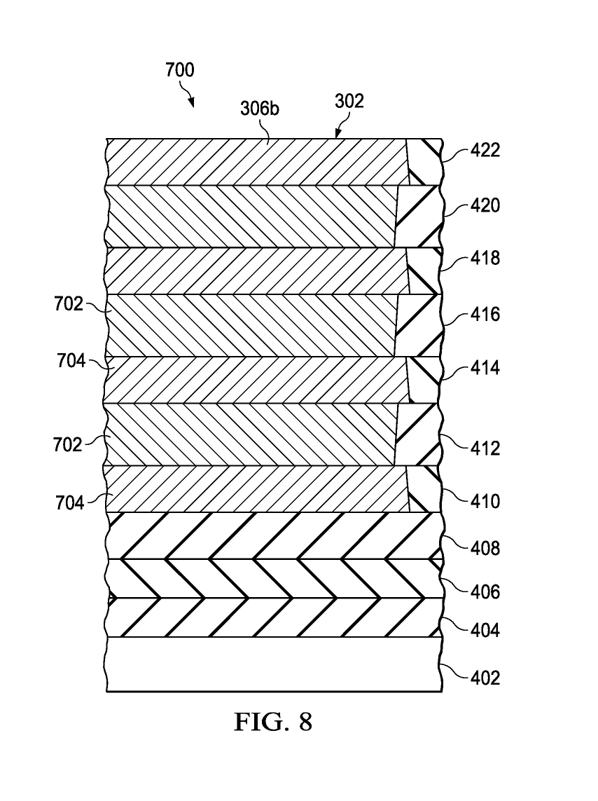

FIG. 7 is a top perspective cut-away view of another example capacitor 700 similar to the example capacitor 300 of FIGS. 3-6. FIG. 8 is a cross-sectional view of the example capacitor 700 of FIG. 7 taken along line 8-8 of FIG. 7. In other words, FIG. 8 is a cross-sectional view (similar to FIG. 6) taken along the length of the center tooth 306b of the first electrode 302 of FIG. 7. As with FIGS. 3-6, the example capacitor 700 of FIGS. 7 and 8 includes conductive vias 702 interconnecting metal segments 704 in adjacent ones of the metal layers 410, 414, 418, 422. The metal segments 704 of FIG. 7 are arranged substantially the same as the metal segments 424 of FIG. 4. The example capacitor 700 of FIG. 7 differs from the example capacitor 300 of FIGS. 3-6 in that the vias 702 in FIG. 7 are elongate strips of metal that extend continuously along a length of the metal segments 704. As used herein, elongate means the length to width ratio is at least 5:1. However, in some examples, the length to width ratio may be substantially higher. In some examples, fabrication of the elongate vias 702 involves the formation of an elongate trench (rather than a discrete hole) within the corresponding IMD layer and then filling the trench with the conductive via material.

The length of the vias 702 may be of any suitable length. In some examples, the vias 702 extend substantially the full length of the corresponding metal segments 704. When the vias 702 extend substantially the full length of the metal segments 704, each of the resulting teeth 306, 308 form a wall or plate of solid metal (e.g., without the gaps 602 of FIG. 6) that takes advantage of the entire area within the plane of each of the teeth 306, 308. The increased area of the teeth 306, 308 results in an increase in the capacitance of the capacitor 700. In some examples, the vias 702 may be formed on the stem portion of the electrodes 302, 304 (e.g., the stem 309 of the second electrode 304 shown in FIG. 7). in addition to the extending along the metal segments 704. In some examples, the vias 702 along each of the metal segments 704 and the corresponding stem 309 are combined or integrated together. In other examples, they may be separated.

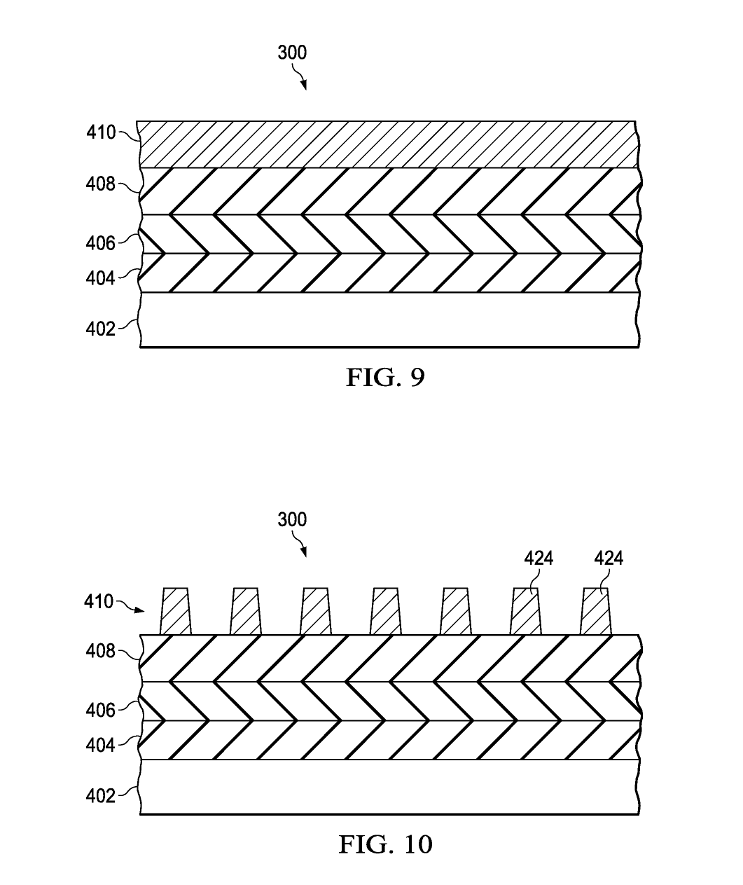

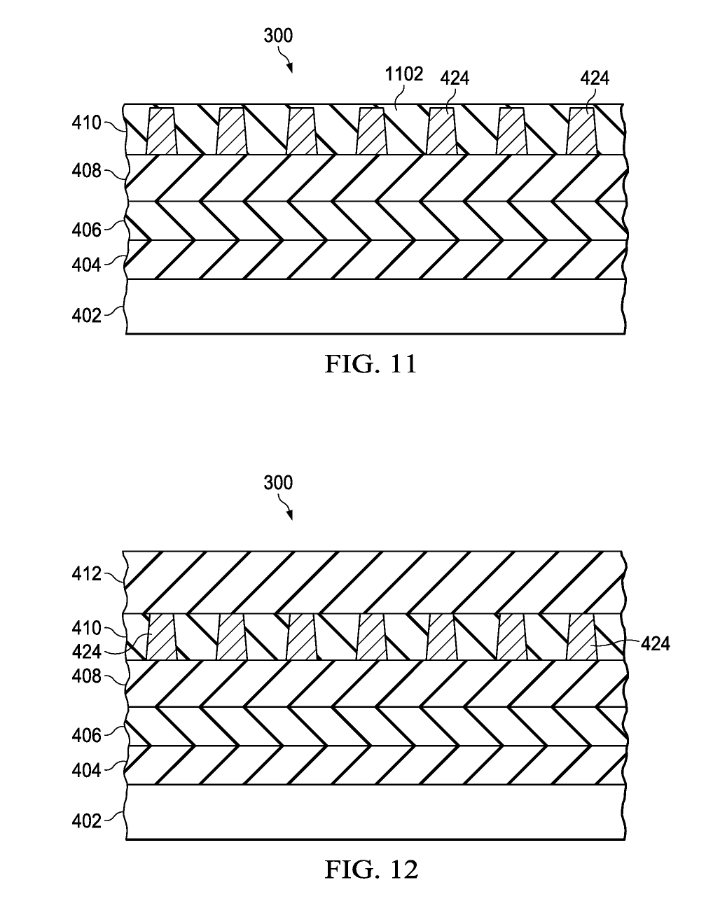

FIGS. 9-14 illustrate progressive stages in the manufacturing of the example capacitor 300 of FIGS. 3-6. While the following description is provided with reference to FIGS. 3-6 for purposes of explanation, the description may be suitably adapted to manufacture the example capacitor 700 of FIGS. 7 and 8. FIG. 9 illustrates the example capacitor 300 formed up to the deposition of metal for the second metal layer 410. FIG. 10 illustrates the second metal layer 410 after an etching process to remove portions of the metal, thereby defining the individual metal segments 424 associated with the separate teeth 306, 308 of the electrodes 302, 304 of the example capacitor 300. FIG. 11 illustrates the second metal layer 410 after the deposition of a dielectric material 1102 to fill in the portions of the metal etched away to electrically isolate the remaining metal segments 424 associated with the electrodes 302, 304. In some examples, as shown in FIG. 11, the dielectric material 1102 is deposited on top of a top surface of the metal segments 424.

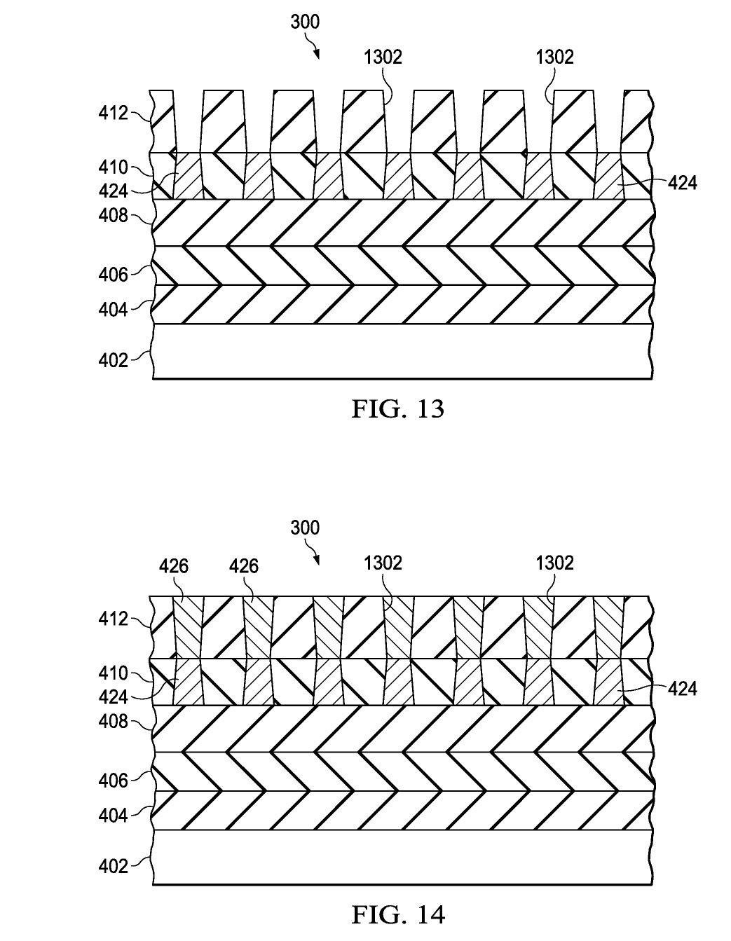

FIG. 12 illustrates the example capacitor 300 after deposition of the second IMD layer 412. FIG. 13 illustrates the second IMD layer 412 after an etching process to define recessed regions 1302 that expose the underlying metal segments 424 and are used to subsequently define the conductive vias 426. This stage of the example process is the only stage that varies between the manufacture of the example capacitor 300 of FIGS. 3-6 and the example capacitor 700 of FIGS. 7 and 8. In particular, for the example capacitor 300 of FIGS. 3-6, the recessed regions 1302 correspond to holes etched into the IMD layer 412 at suitable locations along the lengths of the metal segments 424 defining different teeth 306, 308 for the electrodes 302, 304. By contrast, for the example capacitor 700 of FIGS. 7 and 8, the recessed regions 1302 correspond to elongate trenches etched into the IMD layer 412 that extend along the length of the underlying metal segments 424.

FIG. 14 illustrates the example capacitor 300 after depositing the conductive material for the vias 426 within the recessed regions 1302 in the second IMD layer 412. If the recessed regions 1302 are individual holes, the resulting vias 426 correspond to discrete columns or pillars of conductive material spaced apart along the underlying metal segments 424. If the recessed regions 1302 are trenches, the resulting vias 426 correspond to continuous strips of conductive material that extend continuously along a length of the underlying metal segments 424.

Subsequently, additional metal layers and IMD layers may be alternately formed on the second IMD layer 412 of FIG. 14 by repeating the stages represented in FIGS. 9-14. As shown in the illustrated examples, the location or arrangement of the metal segments 424 and corresponding vias 426 in successive layers are aligned with the previous layers to enable the vertical stacking of the metal segments 424 with interconnecting vias 426 extending therebetween. Thus, in some examples, the arrangement of the metal segments 424 at each metal layer corresponds to a common pattern that is repeated for each metal layer formed. While the example capacitors 300, 700 of FIGS. 3-8 include five metal layers with conductive vias therebetween, in other examples, a greater or fewer number of metal layers may be formed and interconnected with vias as disclosed herein depending upon the needs of any particular application.

FIG. 15 is a flowchart representative of an example method to manufacture the example capacitors 300, 700 of FIGS. 3-8. The example process begins at block 1502 with the completion of front-end-of-line (FEOL) processing of a semiconductor substrate (e.g., the semiconductor substrate 402 of FIG. 4). At block 1504, the example process forms a pre-metal dielectric (PMD) layer (e.g., the PMD layer 404) on the semiconductor substrate 402. At block 1506, the example process forms a metal layer with a desired pattern defining two electrodes (e.g., the electrodes 302, 304). In some examples, some metal layers (e.g., the first metal layer 406 in FIG. 4) may not include any metal to provide sufficient vertical spacing between the electrodes 302, 304 and the surface of the semiconductor substrate 402 (and any devices formed thereon).

At block 1508, the example process determines whether another metal layer is to be formed. If so, control advances to block 1510 where the example process forms an intermetal dielectric (IMD) layer with conductive vias 426 aligned with the metal segments 424 of the underlying metal layer. In some examples, the vias 426 are formed as spaced apart pillars or columns defined by holes etched into the dielectric material of the IMD layer. In other examples, the vias 426 are continuous, elongate strips defined by trenches formed in the dielectric material of the IMD layer. After formation of the IMD layer (block 1510), control returns to block 1506 to form another metal layer. In some examples, successive metal layers have the same pattern or arrangement so that the metal segments 424 in the separate metal layers may be interconnected by the vias 426 to form vertical walls corresponding to the electrodes 302, 304. If the example process determines that another metal layer is not to be formed (block 1508), the example process of FIG. 15 ends.

Although the example method is described with reference to the flowchart illustrated in FIG. 15, many other methods of manufacturing the example capacitors 300, 700 of FIGS. 3-8 may alternatively be used in accordance with the teachings disclosed herein. For example, the order of execution of the blocks may be changed, and/or some of the blocks described may be changed, eliminated, or combined. Similarly, additional operations may be included in the manufacturing process before, in between, or after the blocks shown in FIG. 15.

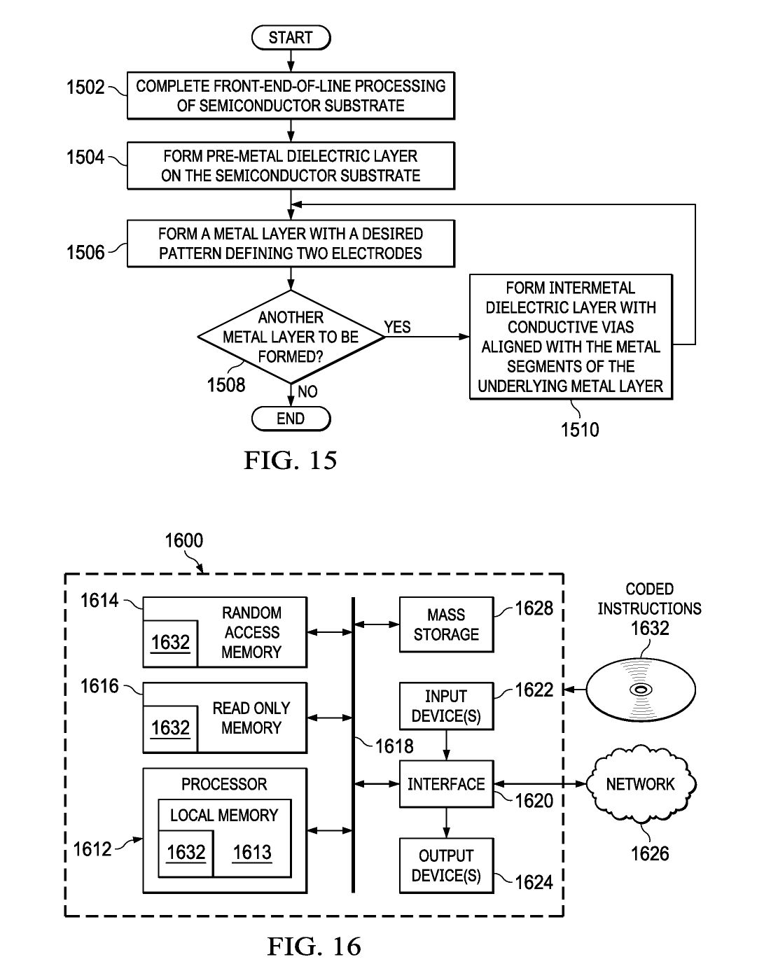

FIG. 16 is a block diagram of an example processor platform 1600 capable of controlling one or more semiconductor fabrication machines to execute the method of FIG. 15 to manufacture the example capacitors 300, 700 of FIGS. 3-8. The processor platform 1600 can be any other type of computing device.

The processor platform 1600 of the illustrated example includes a processor 1612. The processor 1612 of the illustrated example is hardware. For example, the processor 1612 can be implemented by one or more integrated circuits, logic circuits, microprocessors or controllers from any desired family or manufacturer. The hardware processor may be a semiconductor based (e.g., silicon based) device.

The processor 1612 of the illustrated example includes a local memory 1613 (e.g., a cache). The processor 1612 of the illustrated example is in communication with a main memory including a volatile memory 1614 and a non-volatile memory 1616 via a bus 1618. The volatile memory 1614 may be implemented by Synchronous Dynamic Random Access Memory (SDRAM), Dynamic Random Access Memory (DRAM), RAMBUS Dynamic Random Access Memory (RDRAM) and/or any other type of random access memory device. The non-volatile memory 1616 may be implemented by flash memory and/or any other desired type of memory device. Access to the main memory 1614, 1616 is controlled by a memory controller.

The processor platform 1600 of the illustrated example also includes an interface circuit 1620. The interface circuit 1620 may be implemented by any type of interface standard, such as an Ethernet interface, a universal serial bus (USB), and/or a PCI express interface.

In the illustrated example, one or more input devices 1622 are connected to the interface circuit 1620. The input device(s) 1622 permit(s) a user to enter data and/or commands into the processor 1612. The input device(s) can be implemented by, for example, an audio sensor, a microphone, a camera (still or video), a keyboard, a button, a mouse, a touchscreen, a track-pad, a trackball, isopoint and/or a voice recognition system.

One or more output devices 1624 are also connected to the interface circuit 1620 of the illustrated example. The output devices 1624 can be implemented, for example, by display devices (e.g., a light emitting diode (LED), an organic light emitting diode (OLED), a liquid crystal display, a cathode ray tube display (CRT), a touchscreen, a tactile output device, a printer and/or speakers). The interface circuit 1620 of the illustrated example, thus, typically includes a graphics driver card, a graphics driver chip and/or a graphics driver processor.

The interface circuit 1620 of the illustrated example also includes a communication device such as a transmitter, a receiver, a transceiver, a modem and/or network interface card to facilitate exchange of data with external machines (e.g., computing devices of any kind) via a network 1626 (e.g., an Ethernet connection, a digital subscriber line (DSL), a telephone line, coaxial cable, a cellular telephone system, etc.).

The processor platform 1600 of the illustrated example also includes one or more mass storage devices 1628 for storing software and/or data. Examples of such mass storage devices 1628 include floppy disk drives, hard drive disks, compact disk drives, Blu-ray disk drives, RAID systems, and digital versatile disk (DVD) drives.

Coded instructions 1632 to implement the example method of FIG. 15 may be stored in the mass storage device 1628, in the volatile memory 1614, in the non-volatile memory 1616, and/or on a removable tangible computer readable storage medium such as a CD or DVD. As used herein, a non-transitory computer readable storage medium is expressly defined to include any type of computer readable storage device and/or storage disk and to exclude propagating signals and to exclude transmission media.

From the foregoing, it will be appreciated that example methods, apparatus and articles of manufacture have been disclosed that enable the fabrication of high voltage capacitors during BEOL processes with much higher capacitance densities than possible using traditional approaches. Furthermore, the capacitive coupling between electrodes is limited to lateral coupling, thereby enabling precise control of the capacitance by suitably designing the lateral spacing of metal segments within each metal layer during the fabrication process. The teachings disclosed herein may also be implemented for the fabrication of low voltage capacitors to achieve higher capacitance densities that previously possible.

Example 1 is an apparatus that includes a first electrode of a capacitor fabricated on a semiconductor substrate, and a second electrode of the capacitor. The first electrode is separated from the second electrode by a gap to enable capacitive coupling between the first and second electrodes. The first electrode and the second electrode each include: (1) a first metal segment in a first metal layer, (2) a second metal segment in a second metal layer, and (3) a conductive via in an intermetal dielectric layer between the first and second metal layers to electrically interconnect the first and second metal segments.

Example 2 includes the subject matter as defined in Example 1, wherein the conductive via is one of a plurality of conductive vias distributed along a length of the first and second metal segments.

Example 3 includes the subject matter as defined in Example 1, wherein the conductive via is an elongate strip of metal extending along a length of the first and second metal segments.

Example 4 includes the subject matter as defined in Example 1, wherein the intermetal dielectric layer includes an elongate trench. The elongate trench defines a shape of the conductive via.

Example 5 includes the subject matter as defined in Example 1, wherein the capacitor has a voltage rating greater than 80 volts.

Example 6 includes the subject matter as defined in Example 5, wherein the capacitor has a capacitance density of at least 0.02 femtofarads per square micrometer.

Example 7 includes the subject matter as defined in Example 1, wherein the capacitive coupling between the first and second electrodes is oriented to lateral coupling corresponding to a direction parallel to the first and second metal layers.

Example 8 includes the subject matter as defined in Example 1, wherein the first metal segment, the second metal segment, and the conductive via of the first electrode are aligned to form a first wall that is substantially perpendicular to the first and second metal layers. The first metal segment, the second metal segment, and the conductive via of the second electrode are aligned to form a second wall that is substantially parallel (e.g., parallel or within 5 degrees of being parallel) to the first wall.

Example 9 includes the subject matter as defined in Example 1, wherein the first and second electrodes are formed during back-end-of-line processes.

Example 10 is an apparatus that includes a first electrode of a capacitor supported above a surface of a semiconductor substrate. The first electrode includes a first metal segment, a second metal segment, and a first conductive via interconnecting the first and second metal segments. The first metal segment, the first conductive via, and the second metal segment are aligned in a direction substantially perpendicular to the surface of the semiconductor substrate. The apparatus further includes a second electrode of the capacitor supported above the surface of the semiconductor substrate. The second electrode includes a third metal segment, a fourth metal segment, and a second conductive via interconnecting the third and fourth metal segments.

Example 11 includes the subject matter as defined in Example 10, wherein the first and third metal segments are formed in a first metal layer during a first back-end-of-line process. The second and fourth metal segments are formed in a second metal layer during a second back-end-of-line process. The first and second conductive vias are formed in an intermetal dielectric layer between the first and second metal layers during a third back-end-of-line process between the first and second back-end-of-line processes.

Example 12 includes the subject matter as defined in Example 11, wherein the first, second, third, and fourth metal segments are elongate fingers extending along the associated first or second metal layers. The first and second conductive vias are elongate strips of metal extending continuously along substantially a full length of the elongate fingers.

Example 13 includes the subject matter as defined in Example 12, wherein a shape of the first and second conductive vias is defined by elongate trenches formed in the intermetal dielectric layer.

Example 14 includes the subject matter as defined in Example 10, wherein the capacitor has a voltage rating of at least 100 volts.

Example 15 includes the subject matter as defined in Example 10, wherein the first electrode is spaced apart from the second electrode to enable capacitive coupling between the first and second electrodes in a lateral direction substantially parallel to the surface of the substrate without capacitive coupling between the first and second electrodes in a direction substantially perpendicular to the surface of the semiconductor substrate.

Example 16 is a method to manufacture a capacitor that includes forming a first metal layer supported above a semiconductor substrate. The first metal layer includes a first metal segment associated with a first electrode of the capacitor and a second metal segment associated with a second electrode of the capacitor. The method further includes forming an intermetal dielectric layer on the first metal layer. The method also includes forming a second metal layer on the intermetal dielectric layer. The second metal layer including a third metal segment associated with the first electrode and a fourth metal segment associated with the second electrode. The intermetal dielectric layer includes a first conductive via interconnecting the first and third metal segments and a second conductive via interconnecting the second and fourth metal segments.

Example 17 includes the subject matter as defined in Example 16, wherein the first and second conductive vias correspond to elongate strips of metal.

Example 18 includes the subject matter as defined in Example 17, wherein the forming the intermetal dielectric layer includes: depositing a dielectric material on the first metal layer, and etching elongate trenches within the dielectric material. The elongate trenches align with and exposing the first and second metal segments. The forming the intermetal dielectric layer further includes depositing the metal for the first and second conductive vias in the elongate trenches.

Example 19 includes the subject matter as defined in Example 17, wherein a first arrangement of the first and second metal segments and a second arrangement of the third and fourth metal segments correspond to a common pattern for both the first and second metal layers.

Example 20 includes the subject matter as defined in Example 17, wherein a combined shape of the first metal segment, the first conductive via, and the third metal segment corresponds to a wall of solid metal along a plane substantially perpendicular to a surface of the semiconductor substrate.

Example 21 includes an apparatus that includes a capacitor including a first electrode above a semiconductor substrate. The first electrode is parallel to a plane perpendicular to the substrate. The capacitor also includes a second electrode spaced apart from the first electrode and parallel to the plane. The first electrode and the second electrode each including: (1) a first metal segment in a first metal layer, (2) a second metal segment in a second metal layer, and (3) a conductive via in an intermetal dielectric layer between the first and second metal layers interconnecting the first and second metal segments.

Although certain example methods, apparatus and articles of manufacture have been disclosed herein, the scope of coverage of this patent is not limited thereto. On the contrary, this patent covers all methods, apparatus and articles of manufacture fairly falling within the scope of the claims of this patent.

What is claimed is:

1. An apparatus, comprising a capacitor having:
a first electrode above a semiconductor substrate, the first electrode parallel to a plane perpendicular to the substrate; and
a second electrode spaced apart from the first electrode and parallel to the plane, wherein the first electrode and the second electrode each includes: (1) a first metal segment in a first metal layer, (2) a second metal segment in a second metal layer, and (3) a conductive via in an intermetal dielectric layer between the first and second metal layers interconnecting the first and second metal segments.

2. The apparatus as defined in claim 1, wherein the conductive via is one of a plurality of conductive vias distributed along a length of the first and second metal segments.

3. The apparatus as defined in claim 1, wherein the conductive via is an elongate strip of metal extending along a length of the first and second metal segments.

4. The apparatus as defined in claim 1, wherein the intermetal dielectric layer includes an elongate trench, the elongate trench defining a shape of the conductive via.

5. The apparatus as defined in claim 1, wherein the capacitor has a voltage rating greater than 80 volts.

6. The apparatus as defined in claim 5, wherein the capacitor has a capacitance density of at least 0.02 femtofarads per square micrometer.

7. The apparatus as defined in claim 1, wherein the capacitive coupling between the first and second electrodes is oriented to lateral coupling corresponding to a direction parallel to the first and second metal layers.

8. The apparatus as defined in claim 1, wherein the first metal segment, the second metal segment, and the conductive via of the first electrode are aligned to form a first wall that is substantially perpendicular to the first and second metal layers, and wherein the first metal segment, the second metal segment, and the conductive via of the second electrode are aligned to form a second wall that is substantially parallel to the first wall.

9. The apparatus as defined in claim 1, wherein the first and second electrodes are formed during back-end-of-line processes.

10. An apparatus, comprising:
a first electrode of a capacitor supported above a surface of a semiconductor substrate, the first electrode including a first metal segment, a second metal segment, and a first conductive via interconnecting the first and second metal segments, wherein the first metal segment, the first conductive via, and the second metal segment are aligned in a direction substantially perpendicular to the surface of the semiconductor substrate; and
a second electrode of the capacitor supported above the surface of the semiconductor substrate, the second electrode including a third metal segment, a fourth metal segment, and a second conductive via interconnecting the third and fourth metal segments.

11. The apparatus as defined in claim 10, wherein the first and third metal segments are formed in a first metal layer during a first back-end-of-line process, the second and fourth metal segments formed in a second metal layer during a second back-end-of-line process, the first and second conductive vias formed in an intermetal dielectric layer between the first and second metal layers during a third back-end-of-line process between the first and second back-end-of-line processes.

12. The apparatus as defined in claim 11, wherein the first, second, third, and fourth metal segments are elongate fingers extending along the associated first or second metal layers, the first and second conductive vias being elongate strips of metal extending continuously along substantially a full length of the elongate fingers.

13. The apparatus as defined in claim 12, wherein a shape of the first and second conductive vias is defined by elongate trenches formed in the intermetal dielectric layer.

14. The apparatus as defined in claim 10, wherein the capacitor has a voltage rating of at least 100 volts.

15. The apparatus as defined in claim 10, wherein the first electrode is spaced apart from the second electrode to enable capacitive coupling between the first and second electrodes in a lateral direction substantially parallel to the surface of the substrate without capacitive coupling between the first and second electrodes in a direction substantially perpendicular to the surface of the semiconductor substrate.

16. A method to manufacture a capacitor, the method comprising:
forming a first metal layer supported above a semiconductor substrate, the first metal layer including a first metal segment associated with a first electrode of the capacitor and a second metal segment associated with a second electrode of the capacitor;
forming an intermetal dielectric layer on the first metal layer; and
forming a second metal layer on the intermetal dielectric layer, the second metal layer including a third metal segment associated with the first electrode and a fourth metal segment associated with the second electrode, the intermetal dielectric layer including a first conductive via interconnecting the first and third metal segments and a second conductive via interconnecting the second and fourth metal segments.

17. The method as defined in claim 16, wherein the first and second conductive vias correspond to elongate strips of metal.

18. The method as defined in claim 17, wherein the forming the intermetal dielectric layer includes:
depositing a dielectric material on the first metal layer;
etching elongate trenches within the dielectric material, the elongate trenches aligning with and exposing the first and second metal segments; and
depositing the metal for the first and second conductive vias in the elongate trenches.

19. The method as defined in claim 17, wherein a first arrangement of the first and second metal segments and a second arrangement of the third and fourth metal segments correspond to a common pattern for both the first and second metal layers.

20. The method as defined in claim 17, wherein a combined shape of the first metal segment, the first conductive via, and the third metal segment corresponds to a wall of solid metal along a plane substantially perpendicular to a surface of the semiconductor substrate.
